(19) United States
(12) Patent Application Publication
(10) Pub. No.: US 2016/0289585 A1
(43) Pub. Date: Oct. 6, 2016

(54) THERMAL CHEMICAL VAPOR DEPOSITION COATED PRODUCT AND PROCESS OF USING A THERMAL VAPOR DEPOSITION COATED PRODUCT

(71) Applicant: SILCOTEK CORP., Bellefonte, PA (US)

(72) Inventors: James B. MATTZELA, Port Matilda, PA (US); Min YUAN, State College, PA (US); David A. SMITH, Bellefonte, PA (US); Paul H. SILVIS, Port Matilda, PA (US)

(21) Appl. No.: 14/675,823

(22) Filed: Apr. 1, 2015

(51) Int. Cl. C10M 105/76; C23C 16/44; C23C 16/30

(52) U.S. Cl. CPC C10M 105/76; C23C 16/30; C23C 16/44

(57) ABSTRACT

Thermal chemical vapor deposition coated product and uses of such products are disclosed. A thermal chemical vapor deposition coated product includes a threaded substrate and a lubricious coating on the threaded substrate, the lubricious coating having a coefficient of friction of between 0.05 and 0.58 and being a thermal chemical vapor deposition. A process includes engaging the thermal chemical vapor deposition coated product with a material having mating threads, and applying pressure to the thermal chemical vapor deposition coated product while engaged with the material.

### FIELD OF THE INVENTION

The present invention is directed to thermal chemical vapor deposition coated products and uses of such products. More particularly, the present invention is directed to such products with lubricious coatings.

### BACKGROUND OF THE INVENTION

Often, surfaces of substrates do not include desired performance characteristics. The failure to include specific desired performance characteristics can result in surface degradation in certain environments, an inability to meet certain performance requirements, or combinations thereof. For example, in certain environments, substrate surfaces can be subjected to wear and other undesirable surface activities such as chemical adsorption, catalytic activity, corrosive attack, oxidation, byproduct accumulation or stiction, and/or other undesirable surface activities.

Undesirable surface activities can cause chemisorption of other molecules, reversible and irreversible physisorption of other molecules, catalytic reactivity with other molecules, attack from foreign species, a molecular breakdown of the surface, physical loss of substrate, or combinations thereof.

In particular, the surface of threaded substrates often lacks lubriciousness with respect to mating threaded materials. When these threaded substrates are placed under pressure during use, they frequently experience plastic deformation and melding with the mating threaded material. The plastic deformation and melding leads to galling of the threaded substrate, which can contribute to substrate degradation and/or damage.

To provide certain desired performance characteristics, a lubricant may be applied to the threaded substrate and/or the mating threaded material. However, it can be difficult to uniformly apply lubricants to a substrate, or to ensure that the mating threaded materials are sufficiently lubricated as the threaded substrate engages the mating threaded material. Additionally, lubricants can be expensive, difficult to control, and may contaminate other surfaces adjacent to the mating threaded portions.

As an alternative to using lubricants, the threaded substrate may be coated. However, known coatings are typically so thick that they are unworkable on three-dimensional components, such as threaded substrates. For example, current coating thicknesses may cause mating issues when applied to threaded substrates, leading to difficulties in engaging corresponding threaded materials, additional stress to the threaded substrate during use, and/or removal of the coating as the threaded substrate engages the threaded material. For at least these reasons, many industries generally avoid the use of threaded substrates.

Thermal chemical vapor deposition coated products and uses of such products that show one or more improvements in comparison to the prior art would be desirable in the art.

### BRIEF DESCRIPTION OF THE INVENTION

In an embodiment, a thermal chemical vapor deposition coated product includes a threaded substrate and a lubricious coating on the threaded substrate, the lubricious coating having a coefficient of friction of between 0.05 and 0.58 and being a thermal chemical vapor deposition.

In another embodiment, a thermal chemical vapor deposition coated product includes a threaded metallic substrate and a lubricious coating on the threaded metallic substrate, the lubricious coating having a coefficient of friction of between 0.05 and 0.58 and a thickness of between 0.1 micrometers and 2 micrometers. The lubricious coating is formed from thermal chemical vapor deposition of dimethylsilane at a pressure of between 1.0 p.s.i.a and 100 p.s.i.a, at a temperature between 300° C. and 600° C., and for a time of 30 minutes to 24 hours.

In another embodiment, a process includes providing a thermal chemical vapor deposition coated product having a threaded substrate and a lubricious coating on the threaded substrate, the lubricious coating having a coefficient of friction of between 0.05 and 0.58, engaging the thermal chemical vapor deposition coated product with a material having mating threads, and applying pressure to the thermal chemical vapor deposition coated product while engaged with the material. As compared to the threaded substrate being uncoated, the lubricious coating provides a property selected from the group consisting of reduced plastic deformation of the thermal chemical vapor deposition coated product, reduced melding of the threaded substrate with the mating threads of the material, reduced galling of the thermal chemical vapor deposition coated product, and combinations thereof.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 shows a thermal chemical vapor deposition coated product, according to an embodiment of the disclosure.

FIG. 2 shows a cross-section of the thermal chemical vapor deposition coated product of FIG. 1, according to an embodiment of the disclosure.

FIG. 3 shows a cross-section of the thermal chemical vapor deposition coated product of FIG. 1, including a diffusion layer between a threaded substrate and a coating, according to an embodiment of the disclosure.

Wherever possible, the same reference numbers will be used throughout the drawings to represent the same parts.

### DETAILED DESCRIPTION OF THE INVENTION

Provided are a thermal chemical vapor deposition coated product and uses of such products. Embodiments of the present disclosure, for example, in comparison to concepts failing to include one or more of the features disclosed herein, reduce or eliminate plastic deformation of threaded substrates, reduce or eliminate melding of threaded substrates, reduce or eliminate galling of threaded substrates, permit use of a lower thickness of coatings on threaded substrates, permit use of coatings on threaded substrates, permit use of threaded substrates in pressure-impacted processes, or a combination thereof.

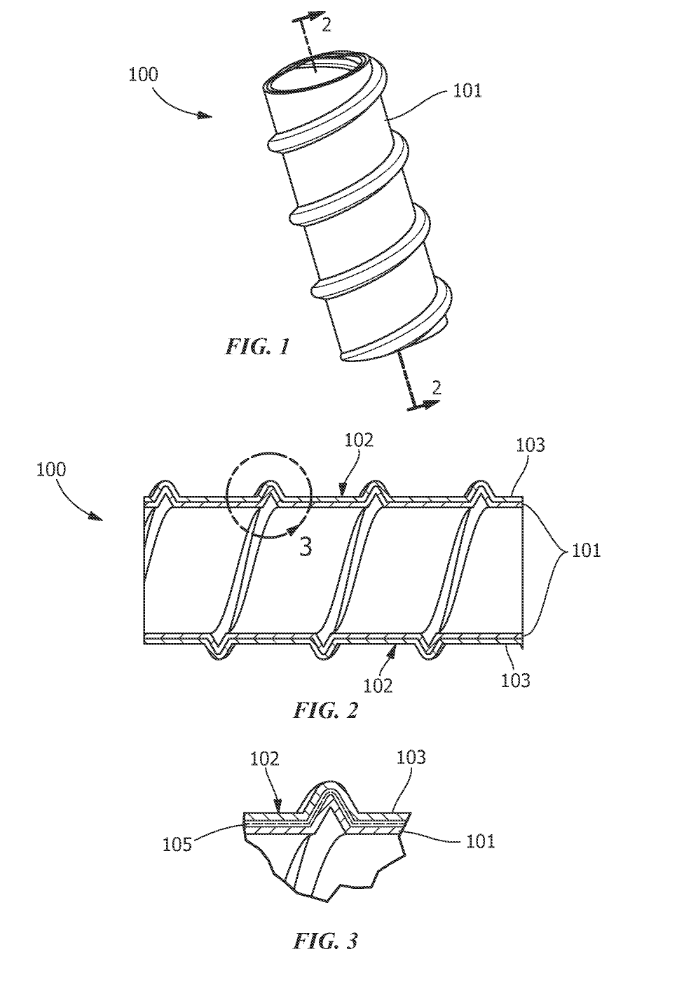

Referring to FIGS. 1-3, a thermal chemical vapor deposition coated product 100 includes a threaded substrate 101 and a coating 103 positioned over the substrate 101. The coating 103 forms a lubricious surface 102 on the threaded substrate 101. The threaded substrate 101 includes any suitable material, such as, but not limited to, metallic materials, ceramic materials, alloys, or a combination thereof. The coating 103 includes a lubricious coating having a coefficient of friction that is less than that of the substrate 101. For example, one suitable coating includes a lubricious silicon oxide coating. As used herein, “lubricious” refers to any surface having a coefficient of friction of less than 0.75. For example, the coefficient of friction is capable of being less than 0.75, less than 0.65, less than 0.6, between 0.01 and 0.6, between 0.05 and 0.6, between 0.05 and 0.58, between 0.1 and 0.55, or any combination, sub-combination, range, or sub-range thereof.

In one embodiment, the coating 103 is formed from decomposition of a silane material, such as, but not limited to, dimethylsilane, trimethylsilane, or a combination thereof. As disclosed in U.S. patent application Ser. No. 13/876,328, and U.S. patent application Ser. No. 13/504,533, both of which are incorporated herein by reference in their entirety, a process for forming the coating 103 includes chemical vapor deposition (CVD) of dimethylsilane. The thermal chemical vapor deposition is by thermal application and not plasma-assisted methods.

In one embodiment, forming the coating 103 over the substrate 101 through the CVD includes thermally decomposing dimethylsilane and/or any other suitable thermal decomposition gas and depositing amorphous carbosilane. In general, suitable species of the decomposition gas include, but are not limited to, an organosilane, dimethylsilane, any silane gas, or any other suitable chemical vapor decomposition gas. Other suitable materials for the introducing and/or subsequent treatment include, but are not limited to, trimethylsilane, dialkylsilyl dihydride, alkylsilyl trihydride, dialkylsilyl dihydride, alkylsilyl trihydride, organofluorotrialkoxysilanes, and/or organofluorosilylhydrides.

Any portion of the chemical vapor deposition process is capable of being preceded or followed by selectively applying a purge gas to the chemical vapor deposition chamber. The purge gas is nitrogen, helium, argon, or any other suitable inert gas. The purging is in one purge cycle, two purge cycles, three purge cycles, more than three purge cycles, or any suitable number of purge cycles that permits chemical vapor deposition chamber to be a chemically inert environment. The purging to provide a chemically inert environment is capable of eliminating or substantially eliminating exposure of the threaded substrate 101 to a corrosive environment, which facilitates the forming of the coating 103.

In one embodiment, prior to forming the coating 103, the threaded substrate 101 is modified to receive a CVD coating. Modifying the threaded substrate 101 includes any suitable treatment method. For example, modifying the threaded substrate 101 is capable of being achieved by isolating the threaded substrate 101 in a chemical vapor deposition chamber, preheating the threaded substrate 101, flushing the chamber with an inert gas, and evacuating the chamber. The modifying of the threaded substrate 101 is capable of increasing adherence of the coating 103 to the threaded substrate 101, which increases wear resistance of the thermal chemical vapor deposition coated product 100. In addition, modifying the threaded substrate 101 through desorbing water is capable of reducing or eliminating corrosion and/or fouling of the thermal chemical vapor deposition coated product 100.

In one embodiment, isolating of the threaded substrate 101 is performed in an inert atmosphere within the chamber. The flow of gas and/or maintenance of a vacuum in the chamber provides the controlled atmosphere. A heat source controls the temperature in the chamber to desorb water and remove remaining contaminants from the threaded substrate 101. For example, in a further embodiment, the threaded substrate 101 to be treated is included within a chemical vapor deposition chamber with tubing connections to allow gas flow in and out of the chemical vapor deposition chamber. The chamber includes multiple controlled inlets and outlets configured for providing and removing multiple gas streams and/or a vacuum to one or more outlet tubes.

Depending upon the cleanliness of the threaded substrate 101, in one embodiment, the threaded substrate 101 is prepared by heating at a temperature above 100° C. and a pressure of below 1 atmosphere for a period ranging from a few minutes to 15 hours. Generally, the temperature of the heating corresponds to the properties of the threaded substrate 101. The period is from 0.5 to 15 hours and the heating, for example, is at about 450° C. for about 2 hours. After preparation under vacuum, in a further embodiment, the chamber is selectively flushed with an inert gas and evacuated.

The thermal decomposition of the decomposition gas includes introducing the decomposition gas into a reaction chamber at a pressure and temperature sufficient to decompose the decomposition gas, depositing constituents from the decomposition onto the threaded substrate 101, coating the threaded substrate 101 for a period of time to achieve a thickness, and/or purging the chamber of decomposition gas. For example, in one embodiment, the dimethylsilane is introduced into the reaction chamber under reduced pressure or with an inert gas, such as nitrogen, helium, and/or argon, as a partial pressure dilutant. After introduction into the reaction chamber, the dimethylsilane is thermally dissociated into molecular fragments including H, C, Si, and combinations thereof. The thermally dissociated constituents are then deposited onto the threaded substrate 101, thereby forming the coating 103 with a material including silicon, carbon, and hydrogen resulting from decomposition of dimethylsilane.

In one embodiment, at least during the introducing of the decomposition gas, the operating the chemical vapor deposition chamber is substantially devoid of catalyst (for example, being below a level that impacts the process) or devoid of catalyst (for example, being absent at detectable levels and/or being completely absent).

Although not intending to be bound by theory, it is believed that the dimethylsilane thermally decomposes to form carbosilyl fragments, which recombine and bind to the substrate 101. It is believed that the resultant coating includes amorphous carbosilanes having carbon, silicon, and hydrogen on the substrate surface as well as on exposed surfaces of the chamber. The composition of the coating 103 includes a 1:0.95:0.12 ratio of C:Si:O (the small presence of oxygen from a depth of 5 nanometers to 120 nanometers is likely attributed to background noise and trace contamination). In contrast, the composition of dimethylsilane introduced into the chemical vapor deposition chamber has about a 2:1 ratio of C:Si. It is believed that CHₓ (x=0-3) moieties are retained and Si—C bonds are broken thus indicating that the coating 103 includes an amorphous array of Si—C bonding and/or a polycrystalline microstructure. The amorphous array provides additional benefits such as reduced or eliminated cracking or flaking (for example, upon tensile or compressive forces acting on the substrate 100) and/or increased adhesion.

Depending upon the decomposition gas and other parameters, a suitable pressure for the decomposition is between 1.0 pound per square inch absolute (psia) and 250 psia, between 1.0 and 200 psia, between 1.0 psia and 150 psia, between 1.0 psia and 100 psia, between 1.0 psia and 75 psia, between 1.0 psia and 50 psia, between 1.0 psia and 40 psia, between 1.0 psia and 30 psia, between 1.0 psia and 20 psia, between 1.0 psia and 10 psia, between 1.0 psia and 5.0 psia, between 5 psia and 40 psia, 1.0 psia, 5 psia, 40 psia, 100 psia, 200 psia, or any suitable combination, sub-combination, range, or sub-range therein.

Depending upon the decomposition gas and other parameters, a suitable temperature for the decomposition is less than 30° C., less than 60° C., less than 100° C., less than 150° C., less than 200° C., less than 250° C., less than 300° C., less than 350° C., less than 400° C., less than 440° C., less than 450° C., less than 500° C., less than 600° C., between 100° C. and 300° C., between 125° C. and 275° C., between 200° C. and 300° C., between 230° C. and 270° C., between 300° C. and 600° C., between 400° C. and 500° C., or any suitable combination, sub-combination, range, or sub-range therein.

Depending upon the decomposition gas and other parameters, a suitable period of time for the decomposition are between 10 minutes and 24 hours, between 1 hours and 10 hours, between 2 hours and 10 hours, between 4 hours and 6 hours, between 4 hours and 8 hours, at least 10 minutes, at least 1 hours, at least 4 hours, at least 10 hours, less than 10 hours, less than 8 hours, less than 6 hours, less than 4 hours, or any suitable combination, sub-combination, range, or sub-range therein.

For example, in one embodiment, the dimethylsilane gas is introduced into the reaction chamber at a pressure of between 1.0 psia and 200 psia, and a temperature of between 300° C. and 600° C., and exposed to the threaded substrate 101 for 30 minutes to 24 hours. In another embodiment, the dimethylsilane gas is introduced into the reaction chamber at a pressure of between 5 psia and 40 psia, and a temperature between 400° C. and 500° C., and exposed to the threaded substrate 101 for 15 hours.

In one embodiment, the lubricious surface 102 provided by the coating 103 includes a coefficient of friction of between 0.05 and 0.58, which lowers friction between the thermal chemical vapor deposition coated product 100 and a mating threaded material, as compared to the threaded substrate 101 without the coating 103. The lower friction reduces or eliminates plastic deformation and/or melding of the threaded substrate 101, which prevents or substantially prevents galling of the thermal chemical vapor deposition coated product 100. In another embodiment, the lubricious surface 102 reduces or eliminates reagent retention, carryover, contamination, and/or build-up on the lubricious surface 102, as compared to the threaded substrate 101 without the coating 103. The reduced reagent retention, carryover, contamination, and/or build-up on the lubricious surface 102 facilitates maintaining the coefficient of friction of the lubricious surface 102, which maintains or substantially maintains the reduced friction between the thermal chemical vapor deposition coated product 100 and the mating threaded material. In addition to reagent reactivity, surface activity refers to, but is not limited to, discoloration of the lubricious surface 102 and/or the substrate 101, for example, to produce a blue or purple appearance. Furthermore, reducing or eliminating the surface activity of the thermal chemical vapor deposition coated product 100 increases the resistance of the thermal chemical vapor deposition coated product 100 to corrosion and/or fouling. In corrosive wear the surface reacts with the environment and reaction products are formed on the surface asperities. Attrition of the reaction products then occurs as a result of crack formation, and/or abrasion, in the contact interactions of the materials.

In another embodiment, the thermal chemical vapor deposition coated product 100 is engaged with the mating threaded material, and a pressure is applied to the thermal chemical vapor deposition coated product 100. The reduced friction between the thermal chemical vapor deposition coated product 100 and the mating threaded material, due to the lubricious surface 102 provided by the coating 103, maintains the reduction or elimination of plastic deformation and/or melding of the threaded substrate 101 while the pressure is applied.

In one embodiment, the coating 103 is formed by cold fill deposition. Cold fill deposition includes positioning the threaded substrate 101 in a chemical vapor deposition chamber, then operating the chemical vapor deposition chamber. The operating of the chemical vapor deposition chamber includes purging the chemical vapor deposition chamber, introducing a decomposition gas to the chemical vapor deposition chamber, heating the chemical vapor deposition chamber, or a combination thereof. Throughout the operating of the chemical vapor deposition chamber, the pressure is adjusted or within a range, for example, of between 0.01 psia and 200 psia, between 1.0 psia and 100 psia, between 5 psia and 40 psia, about 1.0 psia, about 5 psia, about 40 psia, about 100 psia, about 200 psia, or any suitable combination, sub-combination, range, or sub-range therein.

The cold fill deposition includes introduction of the decomposition gas at a sub-decomposition temperature that is below the thermal decomposition temperature of the decomposition gas. As used herein, the phrase “sub-decomposition temperature” refers to conditions at which the decomposition gas will not thermally decompose. Depending upon the species of the decomposition gas, suitable sub-decomposition temperatures include, but are not limited to, less than 30° C., less than 60° C., less than 100° C., less than 150° C., less than 200° C., less than 250° C., less than 300° C., less than 350° C., less than 400° C., less than 440° C., less than 450° C., between 100° C. and 300° C., between 125° C. and 275° C., between 200° C. and 300° C., between 230° C. and 270° C., or any suitable combination, sub-combination, range, or sub-range therein.

During and/or after the introducing of the decomposition gas, the operating of the chemical vapor deposition chamber includes heating the chemical vapor deposition chamber to a super-decomposition temperature that is equal to or above the thermal decomposition temperature of the decomposition gas. As used herein, the phrase “super-decomposition temperature” refers to conditions at which the decomposition gas will thermally decompose. Heating the chemical vapor deposition chamber to the super-decomposition temperature in the presence of the decomposition gas forms the coating 103 on at least a surface of the threaded substrate 101, which forms the lubricious surface 102.

The heating of the chemical vapor deposition chamber is at any suitable heating rate from the sub-decomposition temperature to the super-decomposition temperature. Depending upon the species of the decomposition gas, suitable super-decomposition temperatures include, but are not limited to, between 440° C. and 460° C., greater than 460° C., greater than 450° C., greater than 460° C., greater than 480° C., greater than 500° C., or any suitable combination, sub-combination, range, or sub-range therein. Suitable heating rates include, but are not limited to, between 6° C. per minute and 10° C. per minute, between 7° C. per minute and 9° C. per minute, greater than 6° C. per minute, greater than 7° C. per minute, less than 10° C. per minute, less than 9° C. per minute, at 8° C. per minute, or any suitable combination, sub-combination, range, or sub-range therein. At such rates, in one embodiment, the heating of the chemical vapor deposition chamber is for a period of between 3 minutes and 10 minutes, a period of between 5 minutes and 10 minutes, a period of between 7 minutes and 10 minutes, a period of between 3 minutes and 7 minutes, a period of between 3 minutes and 5 minutes, or any suitable combination, sub-combination, range, or sub-range therein.

The cold fill CVD process disclosed herein is capable of providing chemical vapor deposition of the decomposition gas to form the coating 103 on an increased number of substrates. Furthermore, in addition to the advantages disclosed for the coating 103 formed through CVD, the coating 103 formed through cold fill deposition, as disclosed above, is capable of increasing cross-link density of the coating 103.

In one embodiment, as illustrated in FIG. 3, the deposited material diffuses into the threaded substrate 101, forming a diffusion zone 105 extending between the threaded substrate 101 and the coating 103. Subsequent to forming the coating 103, the chamber is capable of being purged of dimethylsilane and volatile, non-deposited carbosilyl fragments. If a thicker deposition layer is desired, deposition conditions are changed. This is accomplished by changing temperature, pressure, time, or combinations thereof. Multiple layers are also capable of being applied by repeating the introduction and thermal decomposition of the dimethylsilane. Together, the one or more layers of the coating 103 form the lubricious surface 102 on the threaded substrate 101.

While a thickness of the coating 103 depends on the geometry of the substrate 101 to be coated and the type of finish required, in an embodiment made according to the methods disclosed herein, the coating 103 has a thickness of less than 3.0 μm, between 0.1 μm and 3.0 μm, between 0.1 μm and 2.5 μm, less than 2.0 μm, between 0.1 μm and 2.0 μm, between 0.2 μm and 2.0 μm, between 0.5 μm and 2.0 μm, less than 1.5 μm, between 0.1 μm and 1.5 μm, or any combination, sub-combination, range, or sub-range thereof. In another embodiment, the diffusion zone 105 is between 0.005 μm and 0.5 μm. For example, in a further embodiment, the coating 103 extends to 0.130 μm and includes a portion of the diffusion zone 105, which extends 0.02 μm, and is identifiable based upon an increased concentration of 0 and reduced in concentration of C and Si (for example, by at least a factor of four).

In one embodiment, the CVD of the dimethylsilane is followed by oxidation to form a carboxysilane and/or silicon oxide. The carboxysilane and/or silicon oxide is lubricious or substantially lubricious, providing a lubricious or substantially lubricious, non-conductive, and/or thermally insulating coating. In contrast to the belief that ceramic coatings are not suitable for threaded substrates due to a porosity of ceramic coatings, the CVD processes disclosed herein form the lubricious surface 102 from a ceramic material. Doing so permits embodiments with the threaded substrates 101 being in applications, such as, but not limited to, vacuum processing, plasma processing, semiconductor process equipment, and/or any other process in which pressure is applied to the thermal chemical vapor deposition coated product 100 while engaged with a mating threaded material. Furthermore, such embodiments are more uniform/homogenous in composition and/or more uniform/homogenous structure (such as, for example, thickness, phase, and/or grain size) as compared to the threaded substrate 101 and/or oxide layers formed directly on the threaded substrate 101. As compared to non-diffusion coatings, embodiments of the lubricious surface 102 formed through CVD of the coating 103 also provide increased chemical resistance, increased inertness, and increased adhesion of the coating 103 to the threaded substrate 101.

Oxidation of the coating 103 includes exposure to any suitable chemical species capable of donating a reactive oxygen species into the coating 103 under predetermined oxidation conditions. In general, oxidation is a bulk reaction that affects the bulk of the coating 103. The oxidation increases hardness and/or wear resistance of carbosilane and functionalized carbosilane-based chemical vapor deposition process materials of the lubricious surface 102. The oxidation is capable of being controlled by increasing or decreasing the temperature within the chamber, the exposure time within the chamber, the type and/or amount of diluent gases, pressure, and/or other suitable process conditions. Control of the oxidation is capable of increasing or decreasing the amount and/or depth of oxidation and, thus, the wear resistance and/or hardness of the lubricious surface 102. By increasing the wear resistance, the oxidation of the lubricious surface 102 increases resistance of the thermal chemical vapor deposition coated product 100 to galling (from both plastic deformation and melding), which occurs when uncoated surfaces of the threaded substrate 101 contact the mating threaded material.

The chemical species for the oxidation of the coating 103 are selected based upon the desired properties of the lubricious surface 102. Suitable chemical species for the oxidation of the coating 103 include, for example, water, oxygen, air, nitrous oxide, ozone, peroxide, and combinations thereof. In one embodiment, the coating 103 is oxidized with water as an oxidizing agent (for example, within a temperature range of 100° C. to 600° C., a temperature range of 300° C. to 600° C., or at a temperature of 450° C.). In this embodiment, the oxidizing lowers the coefficient of friction of the lubricious surface 102 (in comparison to using an oxidizing reagent of air and water), reduces wear resistance of the lubricious surface 102 (for example, in comparison to using an oxidizing reagent of air and water), and forms Si—O—Si groups. The Si—O—Si groups formed in this embodiment are capable of further decreasing or eliminating surface activity of the lubricious surface 102 as compared to an uncoated threaded substrate 101.

In another embodiment, the coating 103 is oxidized with an oxidizing reagent including air and water (for example, within a temperature range of 100° C. to 600° C., a temperature range of 300° C. to 600° C., or at a temperature of 450° C.). In this embodiment, the oxidizing over-oxidizes and reduces an amount of C—H groups (for example, in comparison to using water alone as an oxidizing reagent), reduces an amount of Si—C groups (for example, in comparison to using water alone as an oxidizing reagent), and increases an amount of Si—OH/C—OH groups (for example, in comparison to using water alone as an oxidizing reagent). Depending on the reagents contacting the lubricious surface 102, the reduced amount of C—H and Si—C groups, and/or the increased an amount of Si—OH/C—OH groups are capable of further decreasing or eliminating surface activity of the lubricious surface 102.

In an alternate embodiment, the coating 103 is oxidized with air (only) (for example, within a temperature range of 100° C. to 600° C., a temperature range of 300° C. to 600° C., or at a temperature of 450° C.). In this embodiment, the oxidizing lowers friction of the lubricious surface 102, increases wear resistance of the lubricious surface 102 (for example, in comparison to using an oxidizing reagent of water), and forms Si—O—Si and Si—OH groups. The Si—O—Si and Si—OH groups are capable of further decreasing or eliminating surface activity of the lubricious surface 102.

In one embodiment, the coating 103 is oxidized with nitrous oxide (N₂O). Specifically, N₂O is applied under heat (for example, about 450° C.) with a pressure of substantially pure N₂O in a vessel with carbosilane-coated samples. In this embodiment, the oxidizing over-oxidizes and the over-oxidizing increases an amount of N—H, Si—OH, and/or C-OH groups, and results in having relatively fragile scratch resistance. Alternatively, the oxidizing is performed with ozone. In this embodiment, the oxidizing is believed to reduce wear resistance, reduce chemical resistance, reduce scratch resistance, reduce hardness, and increase acid resistance/corrosion resistance of the lubricious surface 102.

Any other suitable treating steps are performed on the coating 103 after the decomposition gas is introduced, to form the lubricious surface 102. The treating of the coating 103 includes, for example, heating and/or modifying the coating 103 applied over the substrate 101. In one embodiment, the treating includes exposure of the substrate 101 and/or the coating 103 to a suitable organosilane reagent. One suitable organosilane reagent is a trifunctional organosilane that consists of the general formula RR′R″Si—H, where R,R′,R″ are organofunctional groups. Examples of the organofunctional groups are alkyl, aryl, halogenated alkyl and aryl, ketones, aldehydes, acyl, alcohol, epoxy, and nitro-organo groups, and organometallic functionalities. In one embodiment, the organosilane is trimethylsilane.

By modifying and varying the R′ groups, or by using other molecules capable of hydroxyl reactivity, surface properties of the treated lubricious surface 102 (for example, the air-oxidized carboxysilane layer) are adjusted. For example, in one embodiment, the adjustments increase or decrease hardness and wear resistance, inertness, stiction, coking, electrochemical impedance, contact angle, and combinations thereof. The adjustments provided through varying the R′ groups provide physical performance characteristics expanding the applicability of threaded substrates 101 in the semiconductor industry. The R-groups are capable of being formed by hydrocarbons, substituted hydrocarbons, carbonyls, carboxyls, esters, ethers, amines, amides, sulfonic acids, organometallic complexes, and/or epoxides. Although not intending to be bound by theory, it is believed that the moieties of silicon hydride thermally react, via a hydrosilyation mechanism, with unsaturated hydrocarbon groups to covalently bond to the lubricious surface 102 of the threaded substrate 101. In one embodiment, the lubricious surface 102 on all exposed surface within the reaction chamber includes covalently-bound R-groups which include the R-group and carbon, silicon, and hydrogen moieties.

In one embodiment, after forming the coating 103 on the threaded substrate 101, the coating 103 is treated by trimethylsilane. In another embodiment, the coating 103 is oxidized to form the carboxysilane prior to treatment by trimethylsilane. In a further embodiment, after treating the carboxysilane with trimethylsilane, the coating 103 is functionalized. Treatment with the trimethylsilane is capable of increasing (over untreated oxidized and/or functionalized coatings) inertness, corrosion resistance, hydrophobicity, pH resistance, wear resistance and hardness, and combinations thereof. For example, treating the coating 103 is capable of forming the lubricious surface 102 having about a thirty-four-fold improvement in wear resistance over the untreated functionalized coating. Additionally or alternatively, the coating 103 is capable of being adjusted for anti-stiction and anti-coking properties, which reduces or eliminates byproduct accumulation and/or reagent adherence/retention on the lubricious surface 102, as compared to untreated coatings and/or substrates.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A thermal chemical vapor deposition coated product, comprising:
a threaded substrate; and
a lubricious coating on the threaded substrate, the lubricious coating having a coefficient of friction of between 0.05 and 0.58 and being a thermal chemical vapor deposition.

2. The thermal chemical vapor deposition coated product of claim 1, wherein the threaded substrate comprises a threaded metallic substrate.

3. The thermal chemical vapor deposition coated product of claim 2, wherein the lubricious coating reduces a plastic deformation of the thermal chemical vapor deposition coated product during use as compared to an uncoated threaded substrate.

4. The thermal chemical vapor deposition coated product of claim 2, wherein the lubricious coating reduces a melding of mating thread material of the thermal chemical vapor deposition coated product as compared to the threaded substrate being uncoated.

5. The thermal chemical vapor deposition coated product of claim 2, wherein the lubricious coating prevents galling of the threaded metallic substrate.

6. The thermal chemical vapor deposition coated product of claim 1, wherein the lubricious coating is formed from the thermal chemical vapor deposition of dimethylsilane.

7. The thermal chemical vapor deposition coated product of claim 1, wherein the lubricious coating is formed from the thermal chemical vapor deposition of dimethylsilane at a pressure of between 1.0 p.s.i.a and 100 p.s.i.a, at a temperature between 300° C. and 600° C., and for a time of 30 minutes to 24 hours.

8. The thermal chemical vapor deposition coated product of claim 7, wherein the lubricious coating is oxidized.

9. The thermal chemical vapor deposition coated product of claim 8, wherein the lubricious coating is functionalized.

10. The thermal chemical vapor deposition coated product of claim 7, wherein the lubricious coating is treated with trimethylsilane.

11. The thermal chemical vapor deposition coated product of claim 6, wherein the lubricious coating comprises a thickness of between 0.1 micrometers and 2 micrometers.

12. The thermal chemical vapor deposition coated product of claim 1, wherein the lubricious coating has a lower coefficient of friction than the threaded substrate.

13. A thermal chemical vapor deposition coated product, comprising:
a threaded metallic substrate; and
a lubricious coating on the threaded metallic substrate, the lubricious coating having a coefficient of friction of between 0.05 and 0.58 and a thickness of between 0.1 micrometers and 2 micrometers;
wherein the lubricious coating is formed from thermal chemical vapor deposition of dimethylsilane at a pressure of between 1.0 p.s.i.a and 100 p.s.i.a, at a temperature between 300° C. and 600° C., and for a time of 30 minutes to 24 hours.

14. The thermal chemical vapor deposition coated product of claim 13, wherein the lubricious coating is oxidized.

15. The thermal chemical vapor deposition coated product of claim 13, wherein the lubricious coating is functionalized.

16. The thermal chemical vapor deposition coated product of claim 13, wherein the lubricious coating is treated with trimethylsilane.

17. A process, comprising:
providing a thermal chemical vapor deposition coated product having a threaded substrate and a lubricious coating on the threaded substrate, the lubricious coating having a coefficient of friction of between 0.05 and 0.58;
engaging the thermal chemical vapor deposition coated product with a material having mating threads; and
applying pressure to the thermal chemical vapor deposition coated product while engaged with the material;
wherein, as compared to the threaded substrate being uncoated, the lubricious coating provides a property selected from the group consisting of reduced plastic deformation of the thermal chemical vapor deposition coated product, reduced melding of the threaded substrate with the mating threads of the material, reduced galling of the thermal chemical vapor deposition coated product, and combinations thereof.

18. The process of claim 17, wherein the lubricious coating includes a thickness of between 0.1 micrometers and 2 micrometers.

19. The process of claim 17, wherein the lubricious coating is formed from thermal chemical vapor deposition of dimethylsilane.

20. The process of claim 17, wherein the lubricious coating is formed from thermal chemical vapor deposition of dimethylsilane at a pressure of between 1.0 p.s.i.a and 100 p.s.i.a, at a temperature between 300° C. and 600° C., and for a time of 30 minutes to 24 hours.
